(19) United States
(12) Patent Application Publication
(10) Pub. No.: US 2018/0219558 A1
(43) Pub. Date: Aug. 2, 2018

(54) HYBRID SECOND-ORDER NOISE COUPLING TECHNIQUE FOR CONTINUOUS-TIME DELTA-SIGMA MODULATORS

(71) Applicant: Board of Regents, The University of Texas System, Austin, TX (US)

(72) Inventors: Yun Chiu, Allen, TX (US); Bo Wu, San Jose, CA (US)

(21) Appl. No.: 15/884,018

(22) Filed: Jan. 30, 2018

Related U.S. Application Data
(60) Provisional application No. 62/452,223, filed on Jan. 30, 2017.

(51) Int. Cl. H03M 3/00; G01R 27/26; H03M 1/36; H03M 1/00; H03M 1/08; H03M 1/10

(52) U.S. Cl. CPC H03M 3/452; H03M 3/426; G01R 27/2605; H03M 1/1052; H03M 1/36; H03M 1/002; H03M 1/08; H03M 3/458

(57) ABSTRACT

A delta-sigma modulator. The delta-sigma modulator includes a loop filter (LF) and a digital-to-analog converter (DAC) connected to an input of the LF. The delta-sigma modulator also includes an asynchronous successive-approximation register (ASAR) quantizer (QTZ) connected to the DAC. The delta-sigma modulator also includes a second order noise coupling circuit (NC) connected to the ASAR and the DAC.

### RELATED APPLICATIONS

This application claims priority to U.S. Provisional Application 62/452,223, filed Jan. 30, 2017, the entirety of which is hereby incorporated by reference.

### BACKGROUND INFORMATION

### Field

The present disclosure relates to noise coupling techniques for continuous-time delta-sigma modulators.

### Background

Analog-to-digital converters are useful for many different purposes, such as but not limited to when computers receive data taken from sensors that produce analog data. Digital data sometimes takes the form of a sequence of zeroes and ones, which could be called “true” and “false”, and sometimes takes the form of “high” and “low” voltages, e.g., at 5 volts and 0 volts. Analog data is more continuous in nature; for example, a sensor which records a wide range of voltage values in response to some input.

Delta-sigma modulation, also known as ΔΣ or sigma-delta, ΣΔ, is a method for encoding analog signals into digital signals. This method is sometimes embodied in devices known as analog-to-digital converters (ADC). In an analog-to-digital converter, an analog signal is sampled with a sampling frequency and subsequently quantized in a multi-level quantizer into a digital signal.

Delta-sigma modulation is also used to convert high bit-count, low-frequency digital signals into lower bit-count, higher-frequency digital signals as part of the process to convert digital signals into analog as part of a digital-to-analog converter (DAC). Modern sigma-delta converters offer high resolution, high integration, low power consumption, and low fabrication cost, making them a good choice for applications such as measurement and process control.

The first step in delta-sigma modulation is delta modulation. In delta modulation, the change in the signal, referred to as its delta, is encoded, rather than the absolute value of the signal. The result is a stream of pulses, as opposed to a stream of numbers, as is the case with pulse code modulation (PCM). The result is prone to error, addressed by the sigma stage of delta-signa modulation.

Thus, in the second, “sigma”, step, the accuracy of the delta modulation is improved by passing the digital output through a one-bit digital-to-analog converter and then adding the resulting analog signal to the input signal (the signal before delta modulation). This process reduces errors introduced by the delta-modulation. The process of adding the resulting analog signal to the input signal is the “sigma” part of delta-sigma modulation.

Both analog-to-digital converters and digital-to-analog converters can employ delta-sigma modulation. A delta-sigma analog-to-digital converter first encodes an analog signal using high-frequency delta-sigma modulation, and then applies a digital filter to form a higher-resolution but lower sample-frequency digital output. A delta-sigma digital-to-analog converter encodes a high-resolution digital input signal into a lower-resolution but higher sample-frequency signal that is mapped to voltages, and then smoothed with an analog filter.

### SUMMARY

The illustrative embodiments provide for a delta-sigma modulator. The delta-sigma modulator includes a loop filter (LF) and a digital-to-analog converter (DAC) connected to the input of the LF. The delta-sigma modulator also includes an asynchronous successive-approximation register (ASAR) quantizer (QTZ) connected to the DAC. The delta-sigma modulator also includes a second order noise coupling circuit (NC) connected to the ASAR and the DAC.

The illustrative embodiments also provide for a method of operating a delta-sigma modulator, the delta-sigma modulator comprising a LF; a digital-to-analog converter (DAC) connected to the loop filter; an asynchronous successive-approximation register (ASAR) quantizer (QTZ) connected to the DAC; and a second order noise coupling circuit (NC) connected to the ASAR and the DAC. The method includes driving the DAC directly by an output of the ASAR; and stabilizing a modulator loop by performing a unity-gain negative feedback path around the QTZ and the input-feedforward LF.

The illustrative embodiments also provide for a method of manufacturing a delta-sigma modulator. The method includes placing a digital-to-analog converter (DAC) on a chip; placing, on the chip, an asynchronous successive-approximation register (ASAR) quantizer (QTZ) and connected to the DAC; and placing, on the chip, a second order noise coupling circuit (NC) and connected to the ASAR and to the DAC.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 is a block diagram and schematic of a hybrid, second-order noise coupling, continuous-time delta-sigma modulator, in accordance with an illustrative embodiment;

FIG. 2 is a block diagram and schematic of a 4-bit asynchronous successive-approximation-register (ASAR) quantizer (QTZ) having integrated noise-coupling and excess-loop-delay structures, in accordance with an illustrative embodiment;

FIG. 3 is a block diagram and schematic of a 4-bit asynchronous successive-approximation-register (ASAR) quantizer (QTZ) having integrated noise-coupling and excess-loop-delay structures in a first sampling phase of operation, in accordance with an illustrative embodiment;

FIG. 4 is a block diagram and schematic of a 4-bit asynchronous successive-approximation-register (ASAR) quantizer (QTZ) having integrated noise-coupling and excess-loop-delay structures in a second charge redistribution phase of operation, in accordance with an illustrative embodiment;

FIG. 5 is a block diagram and schematic of a 4-bit asynchronous successive-approximation-register (ASAR) quantizer (QTZ) having integrated noise-coupling and excess-loop-delay structures in a third phase of successive-approximation-register bit cycles when in operation, in accordance with an illustrative embodiment;

FIG. 6 is a block diagram and schematic of a 4-bit asynchronous successive-approximation-register (ASAR) quantizer (QTZ) having integrated noise-coupling and excess-loop-delay structures in a fourth residue sampling and saving operation, in accordance with an illustrative embodiment;

FIG. 7 is a block diagram and schematic of a 4-bit asynchronous successive-approximation-register (ASAR) quantizer (QTZ) having integrated noise-coupling and excess-loop-delay structures in a subsequent sample operation, in which two attenuation capacitors take turns saving residues, in accordance with an illustrative embodiment;

FIG. 8 is a schematic of a second order noise coupling circuit, in accordance with an illustrative embodiment;

FIG. 9 is a schematic of element “A1” in FIG. 8, in accordance with an illustrative embodiment;

FIG. 10 is a schematic of element “A2” in FIG. 8, in accordance with an illustrative embodiment;

FIG. 11 is a graph of signal difference to noise ratio (SNDR) and signal to noise ratio (SNR) in decibels (dB) versus R variation expressed as percentage, in accordance with an illustrative embodiment;

FIG. 12 is a graph of the spectra of the digital output of a hybrid delta sigma modulator as described above, clocked at 900 MHz with a 5 MHz, −3.5 dBFS input, without mismatch calibration and without noise coupling, in accordance with an illustrative embodiment;

FIG. 13 is a graph of the spectra of the digital output of a hybrid delta sigma modulator as described above, clocked at 900 MHz with a 5 MHz, −3.5 dBFS input, with mismatch calibration and without noise coupling, in accordance with an illustrative embodiment;

FIG. 14 is a graph of the spectra of the digital output of a hybrid delta sigma modulator as described above, clocked at 900 MHz with a 5 MHz, −3.5 dBFS input, with mismatch calibration and with noise coupling, in accordance with an illustrative embodiment;

FIG. 15 is a graph of frequency in megahertz versus the magnitude in decibels relative to full scale (dBFS) of noise in a delta sigma modulator, in accordance with an illustrative embodiment;

FIG. 16 is a graph of measured signal difference to noise ratio (SNDR) and signal to noise ratio (SNR) in decibels (dB) versus input power amplitude in dBFS, in accordance with an illustrative embodiment;

FIG. 17 is a table showing a summary of measurement results and comparison of the hybrid delta sigma modulator as described above to various prior delta sigma modulators, in accordance with an illustrative embodiment;

FIG. 18 is a block diagram of a monolithic chip implementing a hybrid delta sigma modulator, as described above, in accordance with an illustrative embodiment;

FIG. 19 is a block diagram of a delta-sigma modulator, in accordance with an illustrative embodiment;

FIG. 20 is a flowchart of a method of operating a delta-sigma modulator, in accordance with an illustrative embodiment; and

FIG. 21 is a flowchart of a method manufacturing a delta-sigma modulator, in accordance with an illustrative embodiment.

### DETAILED DESCRIPTION

The illustrative embodiments recognize and take into account that, the conventional analog-to-digital converters that use delta sigma modulation can suffer from low power-efficiency for wide-band applications. Thus, to lower the power, the illustrative embodiments provide for an improved hybrid second-order noise coupling technique for continuous-time delta-sigma modulators. The illustrative embodiments further contemplate electrical circuits for embodying such delta-sigma modulators.

The illustrative embodiments also recognize and take into account that technology advancement has recently made it attractive to replace the flash quantizer (QTZ) in a multibit delta-sigma modulator by an asynchronous successive-approximation-register (ASAR) QTZ to improve the overall power efficiency. However, limited by the SAR throughput, only a small signal bandwidth is achieved. To achieve a wide bandwidth, a lower oversampling ratio (OSR) can be utilized, which dictates more aggressive noise shaping for a constant signal difference to noise ratio, and thus can potentially compromise the stability of the modulator.

The illustrative embodiments can be used to achieve a wide bandwidth in these cases. A discrete-time (DT) noise-coupling (NC) technique circumvents this problem and is suitable for deployment in an SAR-assisted multibit delta sigma modulator. “SAR” stands for “successive-approximation-register”.

In a switched-capacitor SAR, the quantization error, represented by Eq, is naturally produced on the summing node at the end of the SAR bit cycles and can be buffered and injected back into the loop filter (LF) to facilitate noise coupling. In addition, the switched-capacitor SAR digital-to-analog converter also provides a convenient means to incorporate the excess-loop-delay (ELD) compensation in a continuous-time (CT) modulator. Thus, the illustrative embodiments provide for a 10× oversampling ratio (OSR), 4th-order continuous time delta sigma modulator with mixed-mode (discrete time-continuous time (DT-CT)) 2nd-order noise coupling and ELD compensation, all integrated in a 4-bit asynchronous successive-approximation register quantizer (ASAR QTZ).

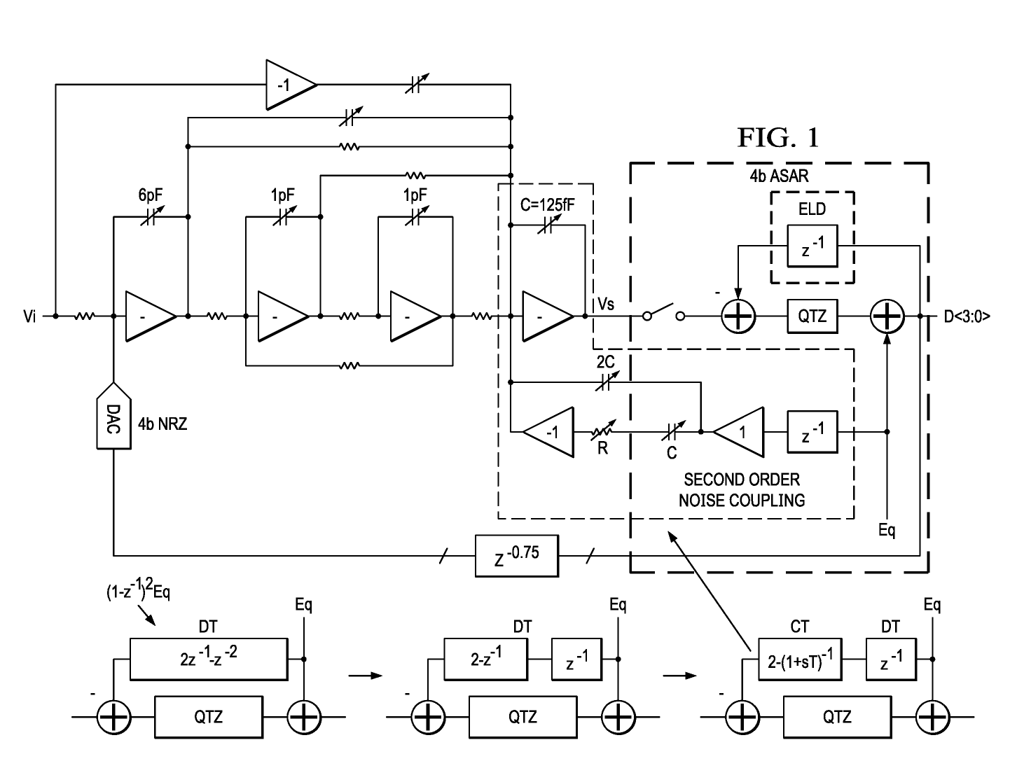

FIG. 1 is a block diagram and schematic of a hybrid, second-order noise coupling, continuous-time delta-sigma modulator, in accordance with an illustrative embodiment. Stated differently, FIG. 1 shows a block diagram of the modulator of the illustrative embodiments using a 4th-order feed-forward (FF) architecture with a 4-bit ASAR QTZ and a 4-bit non-return-to-zero (NRZ) current steering feedback digital-to-analog converter (DAC). The continuous time loop filter (CT LF) adapts an intermediate frequency (IF) band-pass filter (BPF) employing split-path FF-compensated amps. To compensate the process variations, the integration and FF capacitors of the loop filter are designed to be digitally programmable.

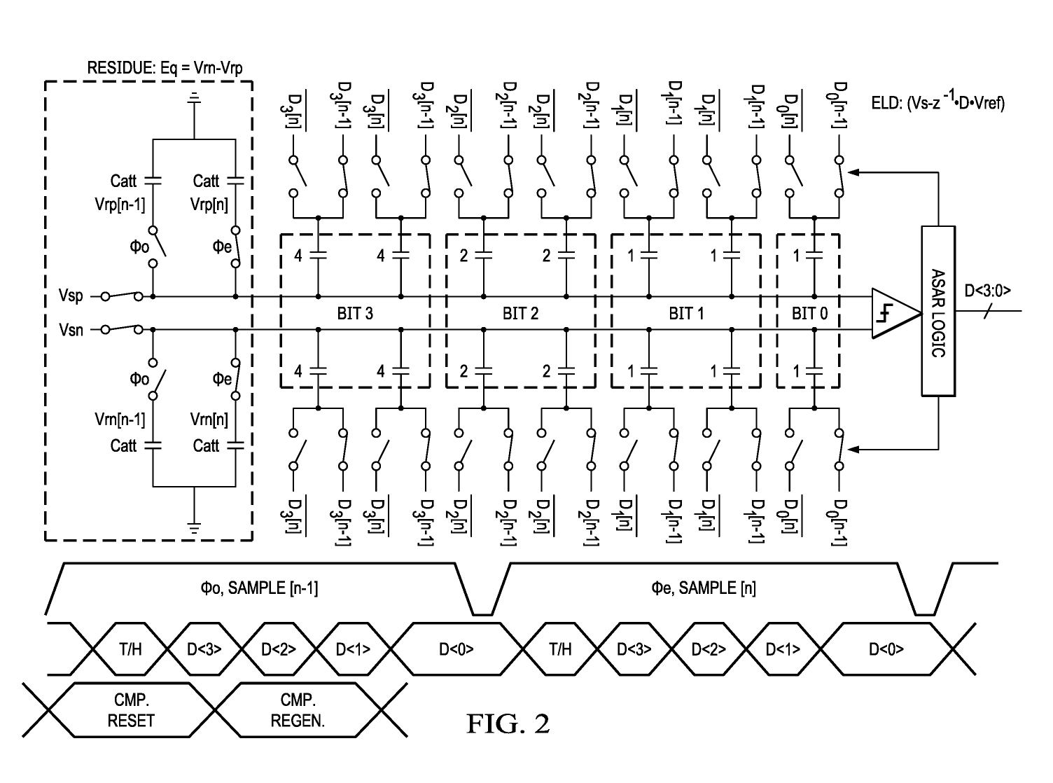

In this illustrative embodiment, a mixed-mode 2^{nd}-order noise coupling structure is implemented, resulting in an overall noise transfer function (NTF) of (1−z⁻¹)²NTF_{LF}, where NTF_{LF} is the 4^{th} order NTF of the loop filter. As graphically explained in FIG. 1, (1−z⁻¹)² is equal to 1−z⁻¹(2−z⁻¹), which is further approximated as 1−z⁻¹(2−(1+sT)⁻¹), the noise coupling structure can be realized by the cascade of a discrete time (DT) part (z⁻¹) and a continuous time part (2−(1+sT)⁻¹), where T is the sample period. The discrete time (DT) part is implemented as described with respect to FIG. 2.

FIG. 2 is a block diagram and schematic of a 4-bit asynchronous successive-approximation-register (ASAR) quantizer (QTZ) having integrated noise-coupling and excess-loop-delay (ELD) structures, in accordance with an illustrative embodiment. Thus, FIG. 2 is part of the 4-bit ASAR shown in FIG. 1.

Continuing the discussion from FIG. 1, the discrete time (DT) part is implemented by switching two pairs of the reference-attenuation capacitors of the successive-approximation-register digital-to-analog converter, shown as two attenuation capacitors (Catts) in FIG. 2, in a ping-pong fashion between odd and even samples to record the residue voltage on the summing node (for example, Eq) after all bit cycles are completed. The continuous time part is implemented by routing the residue voltage on the two attenuation capacitors back to the summing node of the last integrator (for example, INT4) of the loop filter via an RC network with its time constant set to T. All capacitors involved are sized relative to the integration capacitor of INT4, which has a value of 125 fempto Farad. The resistor value is programmable to compensate for process variations.

The noise coupling (NC) and the excess loop delay (ELD) structures are integrated into the 4-bit asynchronous successive-approximation-register quantizer (ASAR QTZ), whose circuit schematic is illustrated in FIG. 2. The successive-approximation-register digital-to-analog converter (ASAR DAC) employs a split capacitor array with top-plate sampling. The total input capacitance of the 4-bit successive-approximation-register (ASAR) is 20 fempto Farad with a power consumption of 1.5 milliwatt clocked at 900 MS/s, in one non-limiting illustrative embodiment.

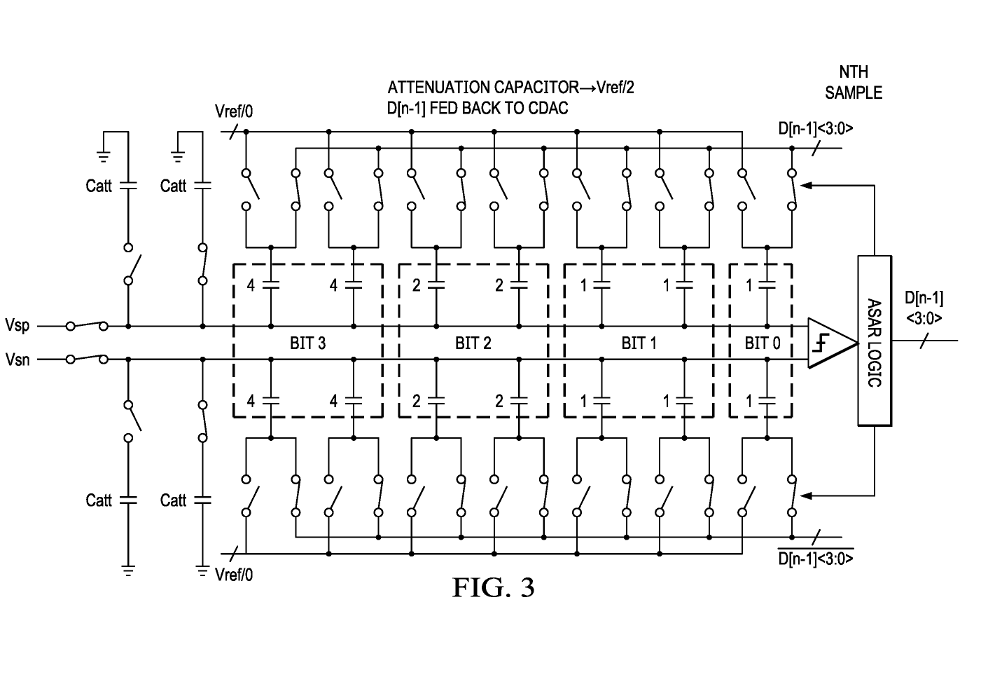

FIG. 3 through FIG. 7 should be read together. Together, these figures show operation of the asynchronous successive-approximation-register quantizer as it ping-pongs switching two pairs of the reference-attenuation capacitors of the successive-approximation-register digital-to-analog converter, as shown in FIG. 2.

FIG. 3 is a block diagram and schematic of a 4-bit asynchronous successive-approximation-register (ASAR) quantizer (QTZ) having integrated noise-coupling and excess-loop-delay structures in a first sampling phase of operation, in accordance with an illustrative embodiment. To begin with, one pair of the attenuation capacitors Cₐₜₜ's are connected to the summing node to halves the reference voltage. The bottom plates of the DAC capacitors are connected to the previously latched digital output D[N−1] of the DAC when the N^{th} sample is being acquired. The net voltage sampled on the capacitor array is thus Vₛ−D[N−1]*V_{ref}′, where V_{ref}′ is the attenuated reference voltage by Cₐₜₜ's.

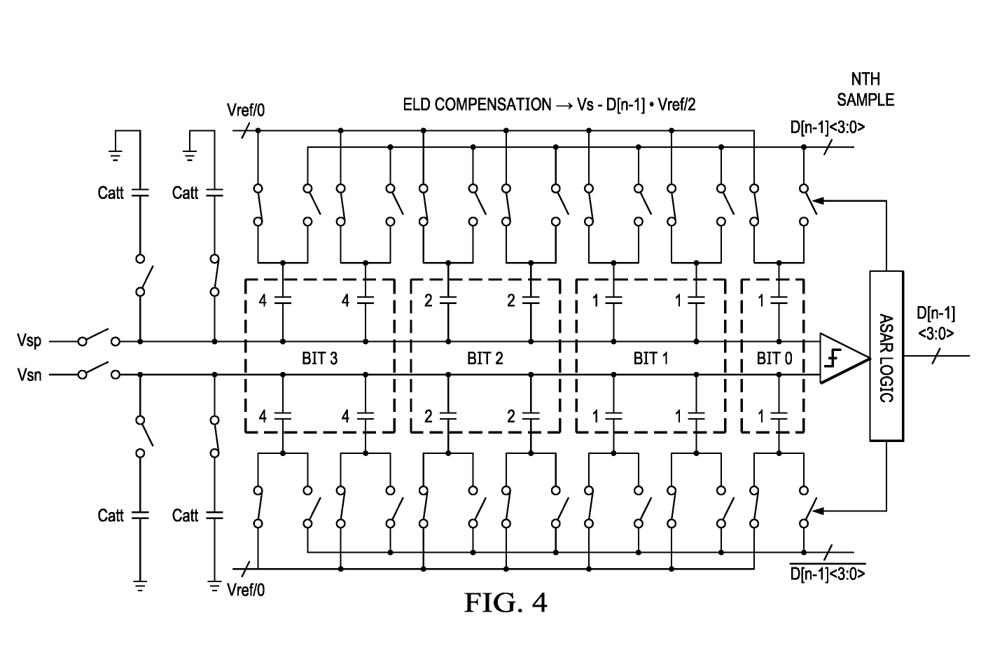

FIG. 4 is a block diagram and schematic of a 4-bit asynchronous successive-approximation-register (ASAR) quantizer (QTZ) having integrated noise-coupling and excess-loop-delay structures in a second charge redistribution phase of operation, in accordance with an illustrative embodiment. In this phase, the bottom plates of the SAR DAC are restored to a common-mode level, thus forcing charge redistribution. The final outcome in this phase is that the ELD-compensated voltage shows up on the summing node, ready to be digitized.

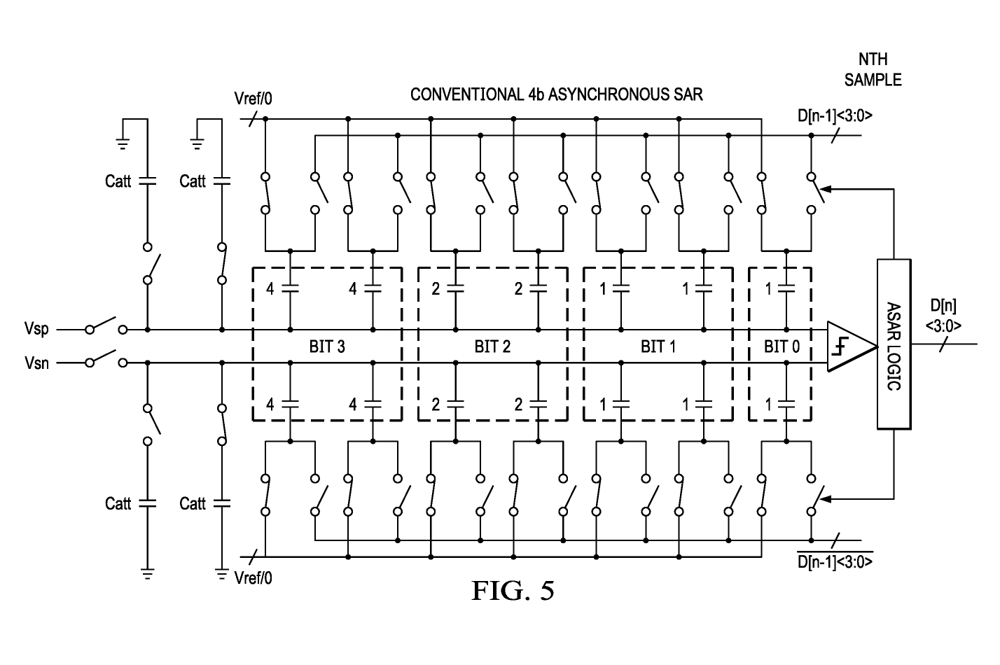

FIG. 5 is a block diagram and schematic of a 4-bit (4b) asynchronous successive-approximation-register (ASAR) quantizer (QTZ) having integrated noise-coupling and excess-loop-delay structures in a third phase of successive-approximation-register bit cycles when in operation, in accordance with an illustrative embodiment. In this phase, for SAR bit cycles are performed and a 4-bit digital output is obtained.

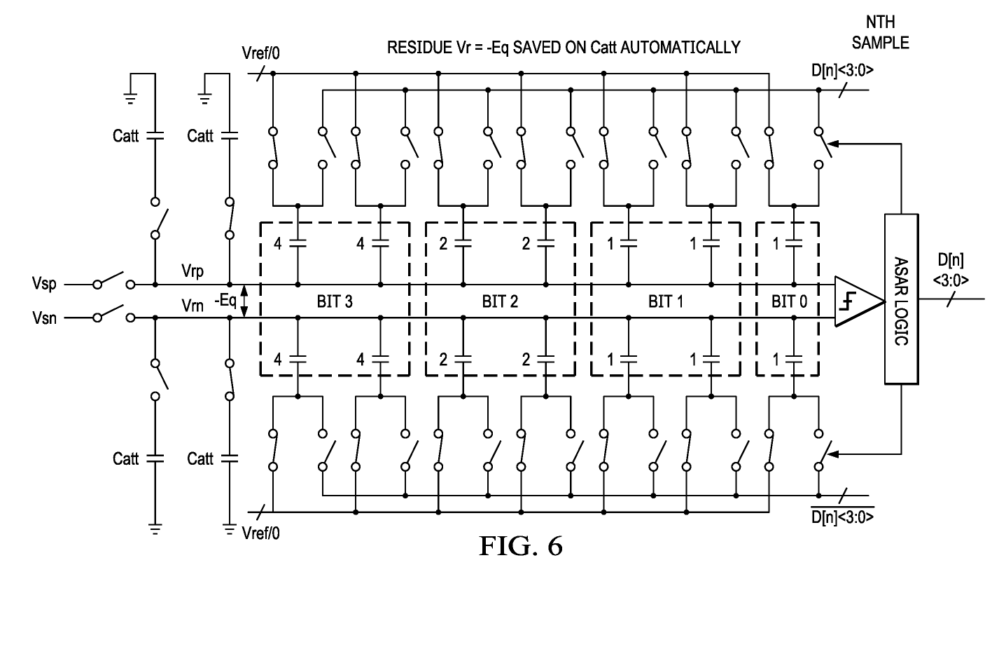

FIG. 6 is a block diagram and schematic of a 4-bit asynchronous successive-approximation-register (ASAR) quantizer (QTZ) having integrated noise-coupling and excess-loop-delay structures in a fourth residue sampling and saving operation, in accordance with an illustrative embodiment. In this phase, after the conversion is done and the residue on the summing node settles, the attenuation capacitors, which store the quantization error (Eq), are disconnected from the summing node. The stored Eq will then be buffered for NC injection.

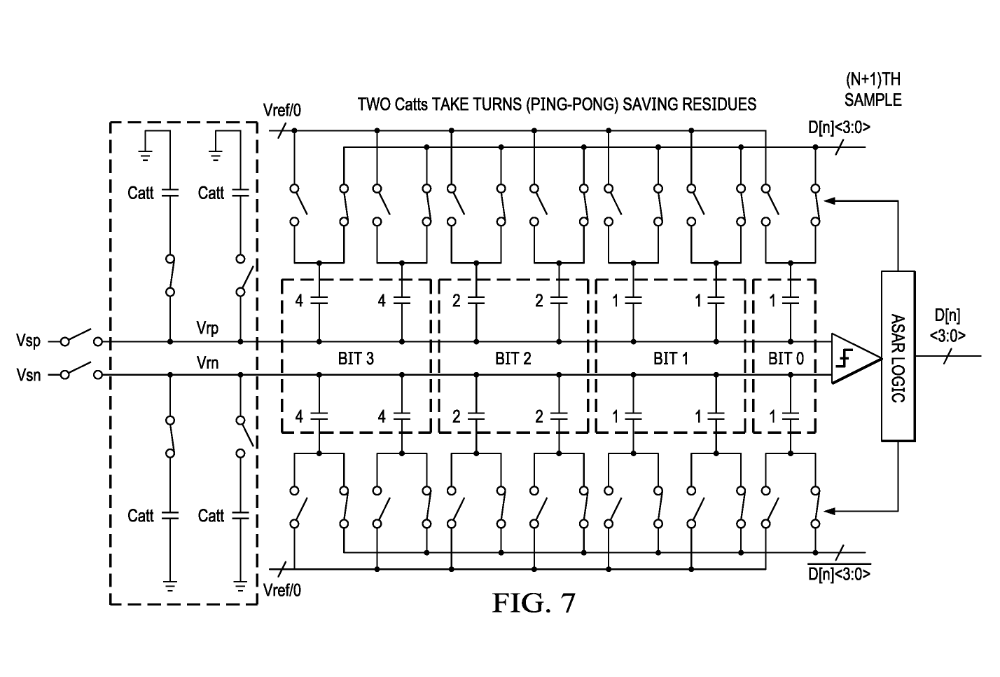

FIG. 7 is a block diagram and schematic of a 4-bit asynchronous successive-approximation-register (ASAR) quantizer (QTZ) having integrated noise-coupling and excess-loop-delay structures in a subsequent sample operation, in which two attenuation capacitors take turns saving residues, in accordance with an illustrative embodiment.

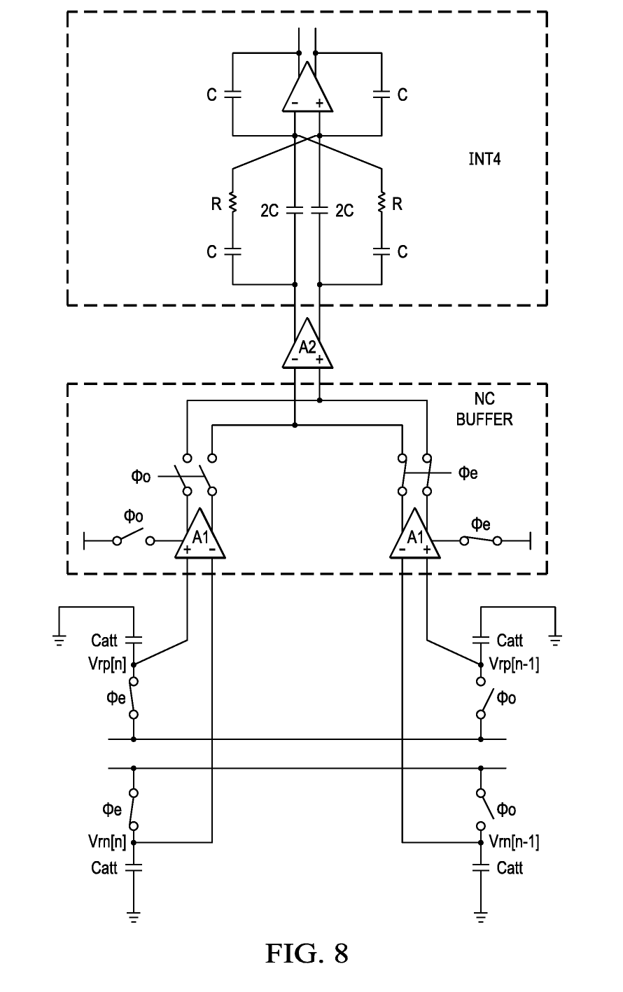

FIG. 8 is a schematic of a second order noise coupling circuit, in accordance with an illustrative embodiment. Specifically, FIG. 8 depicts a detailed schematic of the 2^{nd}-order noise coupling circuit, shown in FIG. 1.

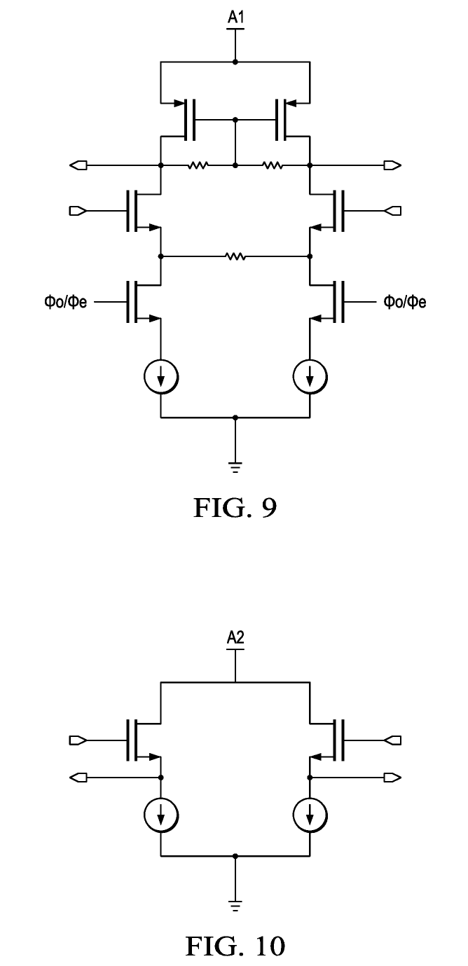

Once the least significant bit (LSB) cycle is done, the residue is sampled by the attenuation capacitors, buffered separately by two degenerated amplifiers (circuit A1 shown in FIG. 9) and a source follower (circuit A2 shown in FIG. 10), and driven into INT4 through an RC network. The two A1 circuits take turns for odd and even samples, respectively, to route Eq or to shut down and save power.

The total nominal gain of the noise coupling buffers is set to unity (the number one). Due to oversampling, the time constant accuracy of the noise canceling circuit is not of critical concern. The measured signal difference to noise ratio (SNDR) of the modulator varies less than 1.4 dB for a ±30% variation of the resistance, R, value, in one illustrative embodiment. In addition, because the nominal residue swing is around 60 mVₚₚ, the linearity of the noise coupling buffers is not of critical concern either, justifying the choice of simple degenerated amplifiers and source follower to buffer the residue.

Lastly, the additional 2nd order noise coupling also helps further shape the quantizer (QTZ) error of the asynchronous successive-approximation-register (ASAR), which translates to improved tolerance to successive-approximation-register (SAR) bit errors as long as the residue settles and is properly fed back to the loop filter (LF) at the end. This fact benefits the conversion speed of the asynchronous successive-approximation-register (ASAR).

The asynchronous successive-approximation-register digital-to-analog converter (ASAR DAC) also allows incorporating the excess loop delay (ELD) compensation easily for the modulator. In FIG. 2, the bottom plates of the digital-to-analog converter (DAC) capacitors are shown to connect to the digital output D[n−1] while the n^{th} sample is being acquired.

The net voltage sampled on the capacitor array is thus Vₛ−D[n−1]*V_{ref}. For example, a unity-gain negative feedback path may be incorporated around the flash quantizer (QTZ) to stabilize the modulator loop for an excess loop delay (ELD) setting of 0.75 T.

In contrast to the conventional excess loop delay (ELD) compensation, this approach obviates the additional feedback digital-to-analog converters (DACs) and simplifies the summing-node connection of the last-stage integrator. In addition, exploiting the successive-approximation-register digital-to-analog converter (SAR DAC) for excess loop delay (ELD) compensation also helps reduce the signal swing seen by the successive-approximation-register quantizer (SAR QTZ). In this manner, the extra quantization levels necessary in a pure digital excess loop delay (ELD) treatment is eliminated, and the system is also less prone to quantization noise.

However, similar to the digital approach, the excess loop delay (ELD) feedback around the quantizer (QTZ) has no effect on reducing the output swing of the last integrator (for example, INT4). Therefore, for this example, the voltage gain of INT4 is also halved to avoid saturation. To maintain a constant loop gain of the delta sigma modulator, the attenuation capacitors (for example, the attenuation capacitors) mentioned earlier are employed to downscale the least significant bit (LSB) size of the asynchronous successive-approximation-register (ASAR) by a factor of two.

A 4-bit binary digital-to-analog converter driven directly by the asynchronous successive-approximation-register (ASAR) output bits is employed to eliminate any additional logic delay in the main feedback path. In this example, the digital-to-analog converter includes fifteen complementary current-steering cells with cascade current sources on both P and N sides, and a switching quad in the middle. However, more or fewer complementary current-steering cells may be present, and thus their number may be characterized as a plurality.

A 1.8V power supply may be used by the digital-to-analog converter to provide sufficient headroom and to lower noise. As digital-to-analog converter nonlinearity causes harmonic distortion and out-of-band cross modulation that can fold back in-band, the static digital-to-analog computer mismatch errors are calibrated using a foreground technique.

For example, a large 1 mega Hertz (MHz) sine wave may be quantized by the modulator, and a curve fitting performed to extract the bit weights of all digital-to-analog converter cells. The obtained bit weights are then recorded in a look-up table to apply to all remaining tests (at different frequencies). The residual memory error and the dynamic errors of the digital-to-analog converter are not compensated during the prototype testing and, if necessary, may be further treated using the memory error model of delta sigma modulators described herein.

FIG. 9 and FIG. 10 should be read together with FIG. 8. In particular, FIG. 9 is a schematic of element “A1” in FIG. 8, in accordance with an illustrative embodiment. Similarly, FIG. 10 is a schematic of element “A2” in FIG. 8, in accordance with an illustrative embodiment.

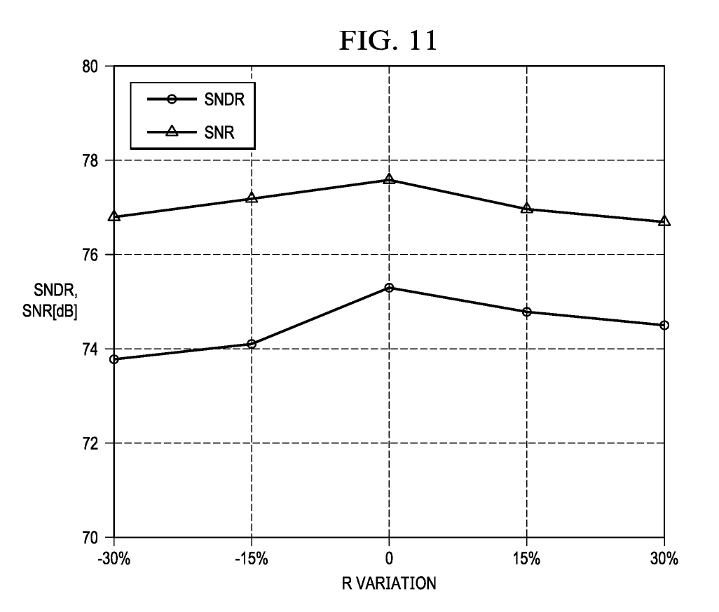

FIG. 11 is a graph of signal difference to noise ratio (SNDR) and signal to noise ratio (SNR) in decibels (dB) versus R variation expressed as percentage, in accordance with an illustrative embodiment. The measured SNDR fluctuation is within 3 dB for a 10% gain variation, which proves the reliability of the proposed method over different process corners.

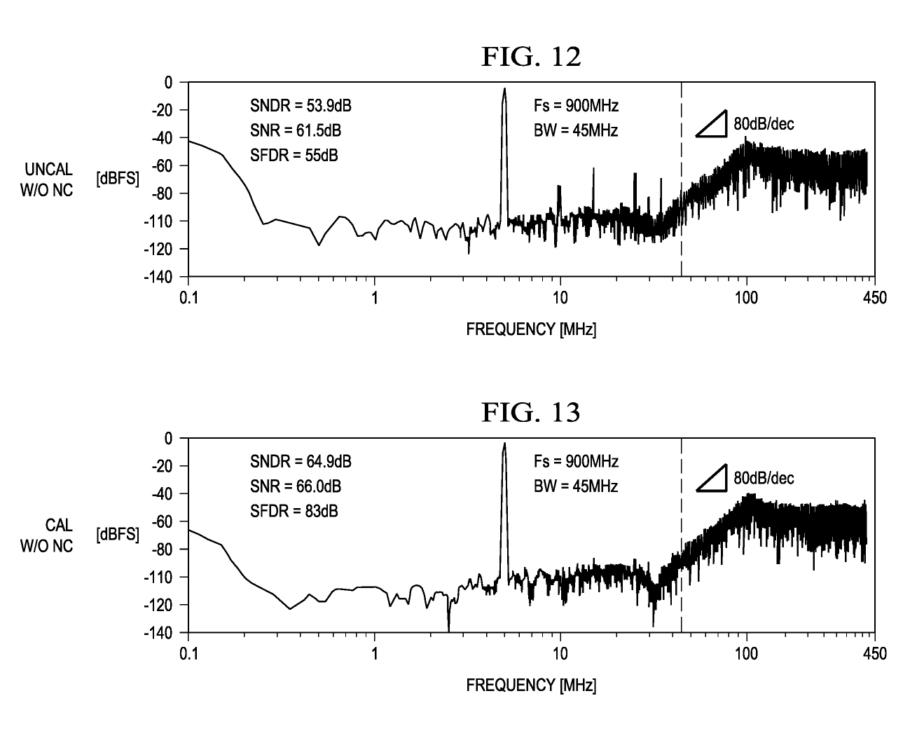

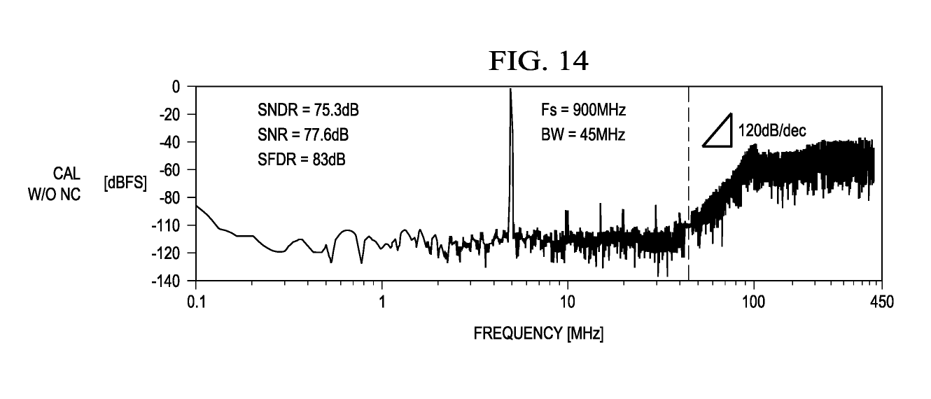

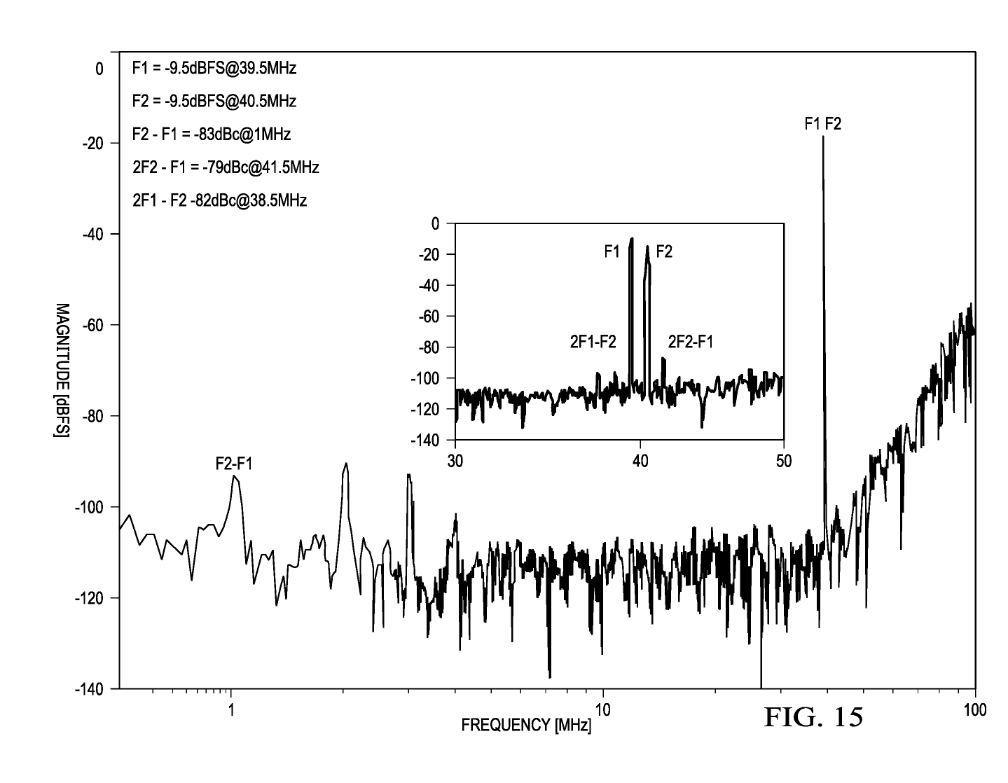

FIG. 12 through FIG. 15 should be read together. FIG. 12 is a graph of the spectra of the digital output of a hybrid delta sigma modulator as described above, clocked at 900 MHz with a 5 MHz, −3.5 dBFS input, without mismatch calibration and without noise coupling, in accordance with an illustrative embodiment. FIG. 13 is a graph of the spectra of the digital output of a hybrid delta sigma modulator as described above, clocked at 900 MHz with a 5 MHz, −3.5 dBFS input, with mismatch calibration and without noise coupling, in accordance with an illustrative embodiment. FIG. 14 is a graph of the spectra of the digital output of a hybrid delta sigma modulator as described above, clocked at 900 MHz with a 5 MHz, −3.5 dBFS input, with mismatch calibration and with noise coupling, in accordance with an illustrative embodiment. FIG. 15 is a graph of frequency in megahertz versus the magnitude in dBFS of noise in a delta sigma modulator, in accordance with an illustrative embodiment;

In one illustrative embodiment, the continuous time delta sigma modulator of the illustrative embodiments is fabricated in a 65 nm complimentary metal-oxide semiconductor (CMOS) process. FIG. 12 through FIG. 14 show the spectra of the digital output of the prototype clocked at 900 MHz with a 5 MHz, −3.5 dBFS input. The measured signal difference to noise ratio (SNDR) is improved from 53.9 dB (raw) to 64.9 dB (with digital-to-analog converter (DAC) calibration only) and eventually to 75.3 dB (with both noise coupling (NC) and digital-to-analog converter (DAC) calibration enabled).

The corresponding spurious-free dynamic range (SFDR) is improved from 55 dB to 83 dB. The 4^{th}-order modulator augmented by the additional 2^{nd}-order noise coupling (NC) achieves a 120 dB/decade slope of the shaped noise, indicating an overall 6th-order noise shaping attained. The in-band signal difference to noise ratio (SNDR) performance is mostly limited by the thermal noise.

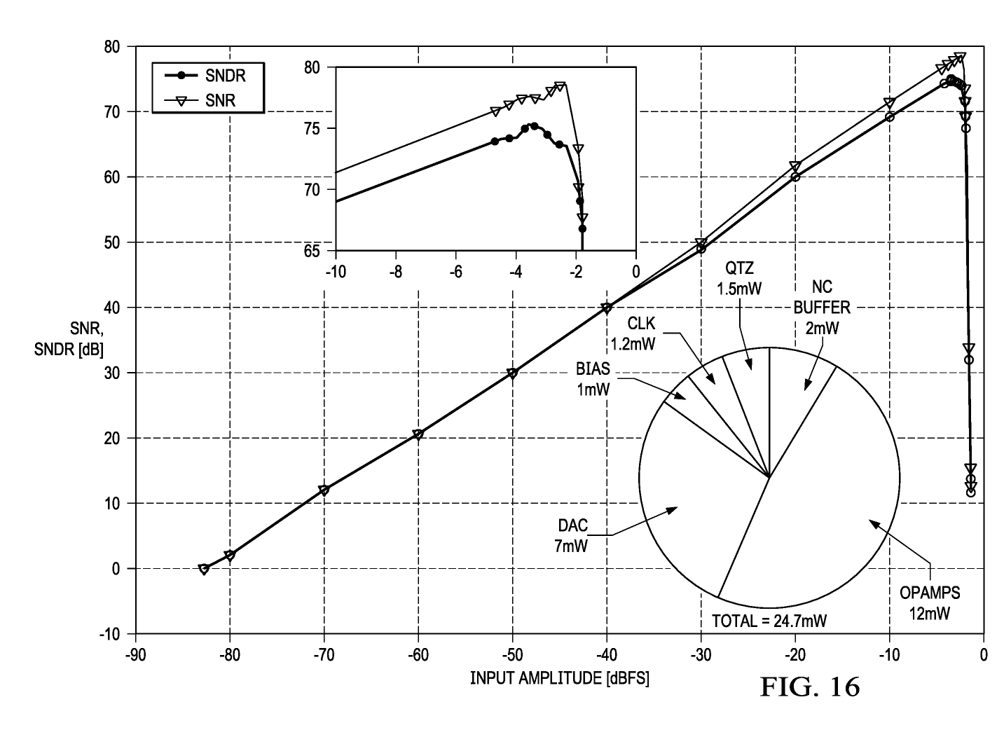

FIG. 16 is a graph of measured signal difference to noise ratio (SNDR) and signal to noise ratio (SNR) in decibels (dB) versus input power amplitude in dBFS, in accordance with an illustrative embodiment. In particular, FIG. 16 shows the measured SNDR/SNR versus the input amplitude. The total consumption is 24.7 mW in this example, of which 14 mW is consumed in the analog portion and 10.7 mW is consumed in the digital portion. The noise coupling buffer consumes 2 mW.

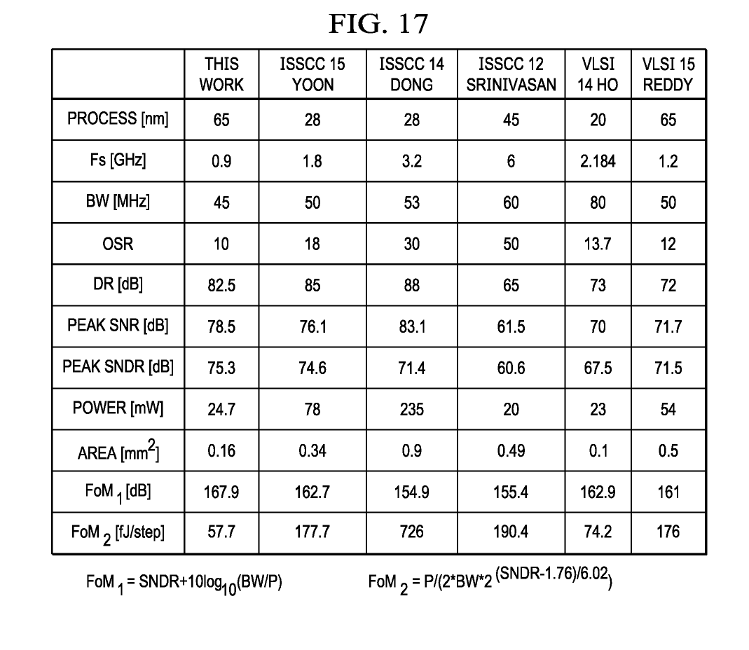

FIG. 17 is a table showing a summary of measurement results and comparison of the hybrid delta sigma modulator as described above to various prior delta sigma modulators, in accordance with an illustrative embodiment. FIG. 17 summarizes the measured performance of the delta sigma modulator of the illustrative embodiments and compares it to other state-of-the-art continuous time delta sigma modulators with a similar bandwidth. Our 65 nm complementary metal oxide semiconductor (CMOS) prototype achieves the highest peak signal difference to noise ratio (SNDR) of 75.3 dB, the highest Schreier figure of merit (FOM) of 167.9 dB (SNDR), and the lowest Walden FOM of 57.7 fempto Joule conversion-step with the lowest oversampling ratio of 10× among the other continuous time delta sigma modulators shown in FIG. 17.

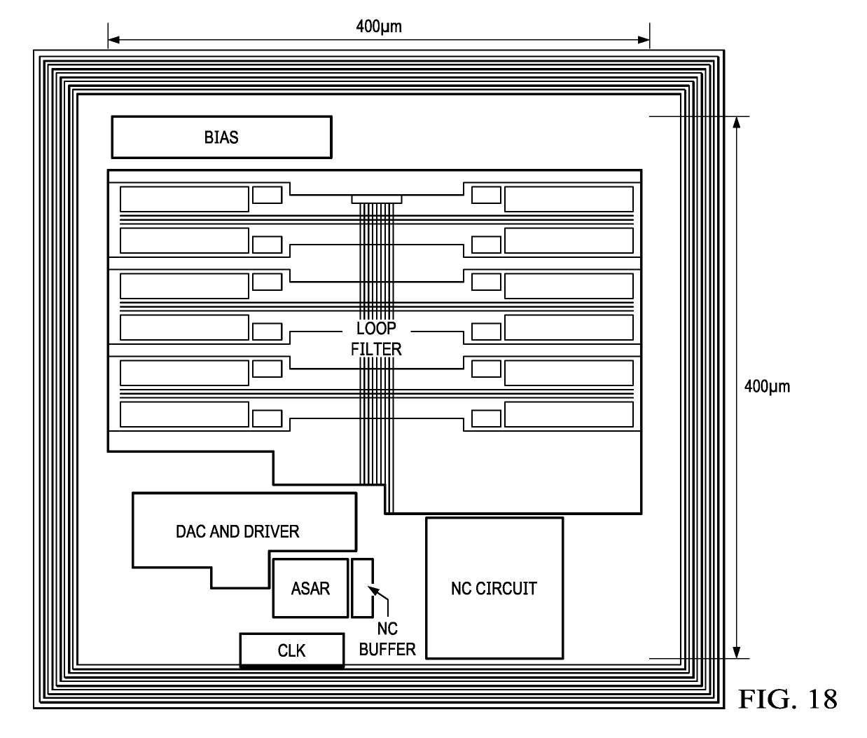

FIG. 18 is a block diagram of a chip implementing a hybrid delta sigma modulator, as described above, in accordance with an illustrative embodiment. Thus, FIG. 18 shows an example of a physical implementation of the delta sigma modulator shown in FIG. 1. In this one example, FIG. 18 shows a die photo of the modulator, which occupies an active area of 0.16=².

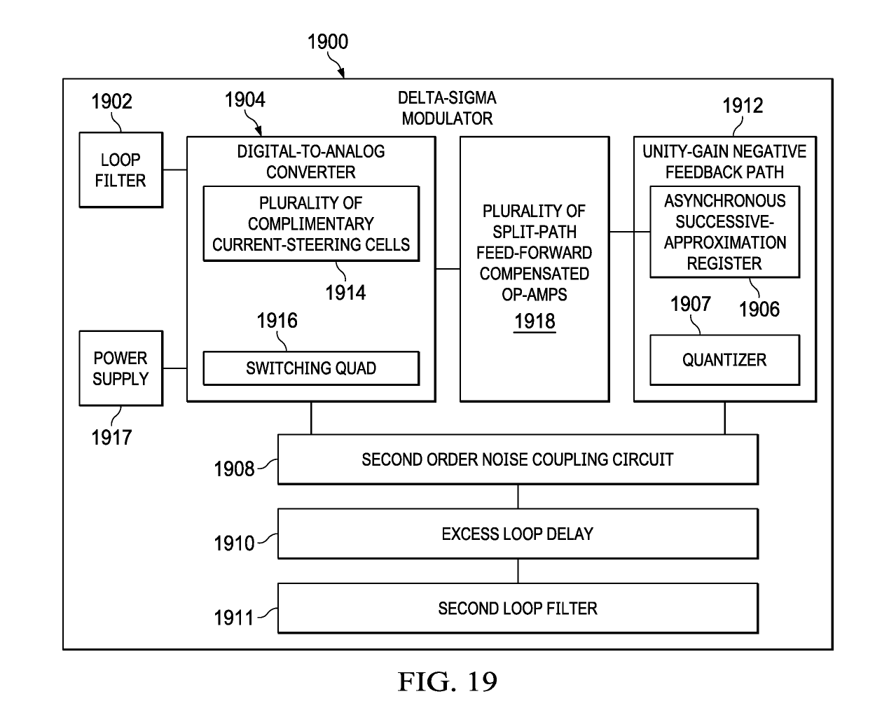

FIG. 19 is a block diagram of a delta-sigma modulator, in accordance with an illustrative embodiment. Delta sigma modulator 1900 is a variation of the hybrid, second-order noise coupling, continuous-time delta-sigma modulator shown in FIG. 1.

Delta-sigma modulator 1900 includes loop filter 1902 (LF). Delta-sigma modulator 1900 also includes digital-to-analog converter 1904 (DAC) connected to an input of loop filter 1902. Delta-sigma modulator 1900 also includes asynchronous successive-approximation register 1906 (ASAR) quantizer 1907 (QTZ) connected to DAC 1904. Delta-sigma modulator 1900 also includes second order noise coupling circuit 1908 (NC) connected to the ASAR 1906 and the DAC 1904.

Delta-sigma modulator 1900 may be varied. For example, for delta-sigma modulator 1900, ASAR 1906 may further include excess loop delay 1910 (ELD) compensator built within the ASAR 1906 QTZ 1907 connected to the NC 1908. In another illustrative embodiment, ELD 1910 may include second loop filter 1911 at an end of the ASAR, the second loop filter 1911 configured to buffer and inject a quantization error from the second order noise coupling circuit 1908 (NC) back into second loop filter 1911.

In another illustrative embodiment, NC 1908 includes a mixed mode discrete time-continuous time second order noise coupler (DT-CT) connected to ASAR 1906. In a further illustrative embodiment, the DT-CT implements a noise transfer function of (1−Z⁻¹)²NTF_{LF}. wherein NTF_{LF} is a fourth order noise transfer function of the loop filter. In a still further illustrative embodiment, a noise coupling structure is realized by a cascade of a discrete time (DT) part and a continuous time (CT) part. In a still further illustrative embodiment, the DT part is implemented by switching two pairs of reference-attenuation capacitors of the DAC. In a still further illustrative embodiment, the CT part is implemented by routing a residue voltage of the two pairs of the reference attenuation capacitors to a summing node of a last integrator of the loop filter via an RC network having a time constant sent to a sample period of the delta-sigma modulator. In a still further illustrative embodiment, all capacitors in the delta-sigma modulator are sized relative to an integration capacitor of the last integrator.

In a still further illustrative embodiment, delta-sigma modulator 1900 also includes unity-gain negative feedback path 1912 incorporated around the QTZ 1907 to stabilize a modulator loop for a predetermined ELD 1910 setting. In a still further illustrative embodiment, DAC 1904 is driven directly by an output of the ASAR 1906.

In a different illustrative embodiment, DAC 1904 includes plurality of complimentary current-steering cells 1914 with cascode current sources on both P and N sides; and switching quad 1916 in a middle of the plurality of complimentary current-steering cells 1914. In a further illustrative embodiment, DAC 1904 is connected to power supply 1917.

In a still different illustrative embodiment, delta-sigma modulator 1900 comprises a fourth-order feed forward architecture. In this case, the DAC 1904 comprises a 4-bit non-return-zero (NRZ) current steering feedback digital-to-analog converter. In yet a different illustrative embodiment, delta sigma modulator 1900 includes plurality of split-path feed-forward compensated op-amps 1918 connected between an output of DAC 1904 and an input of ASAR 1906.

Still other variations are possible. Thus, the illustrative embodiments are not necessarily limited by the examples provided herein.

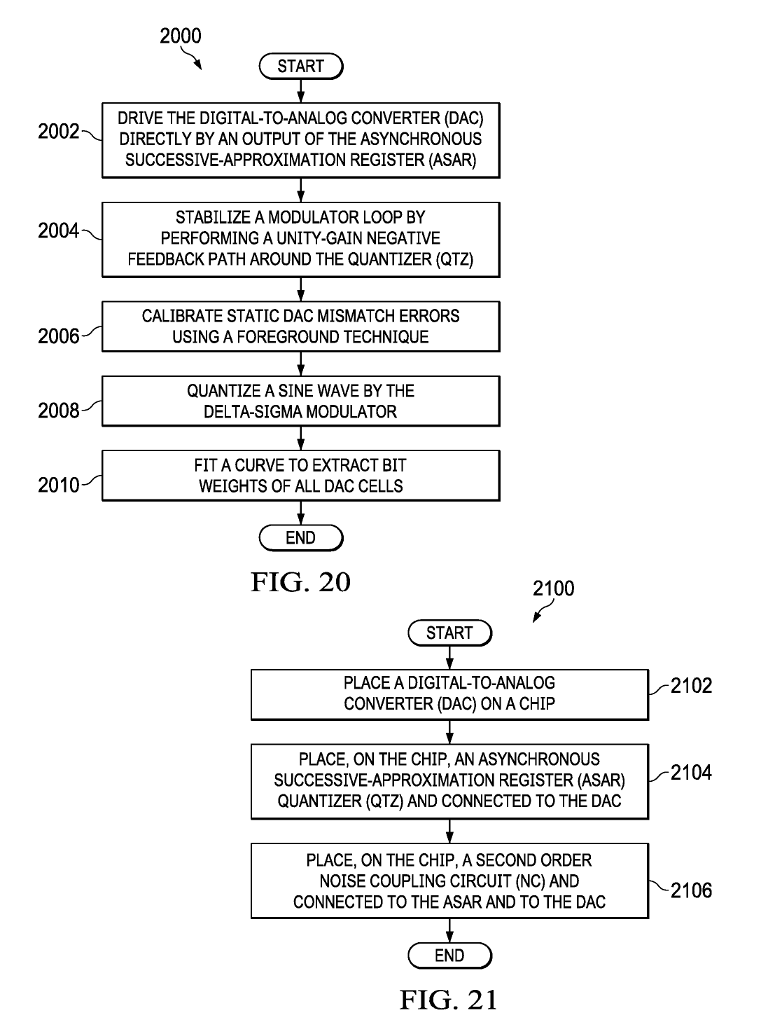

FIG. 20 is a flowchart of a method of operating a delta-sigma modulator, in accordance with an illustrative embodiment. Method 2000 may be implemented using any of the delta sigma modulators described herein, such as that shown in FIG. 1 or that shown in FIG. 19. Method 2000 may be characterized as a method of operating a delta-sigma modulator, the delta-sigma modulator comprising a loop filter (LF); a digital-to-analog converter (DAC) connected to an input of the loop filter; an asynchronous successive-approximation register (ASAR) quantizer (QTZ) connected to the DAC; and a second order noise coupling circuit (NC) connected to the ASAR and the DAC.

Method 2000 includes driving the DAC directly by an output of the ASAR (operation 2002). Method 2000 also includes stabilizing a modulator loop by performing a unity-gain negative feedback path around the QTZ (operation 2004).

Method 2000 may be varied. For example, method 2000 also may include calibrating static DAC mismatch errors using a foreground technique (operation 2006). method 2000 also may include quantizing a sine wave by the delta-sigma modulator (operation 2008); and fitting a curve to extract bit weights of all DAC cells (operation 2010).

Still other variations are possible. Thus, the illustrative embodiments are not necessarily limited to the examples provided in FIG. 20.

FIG. 21 is a flowchart of a method manufacturing a delta-sigma modulator, in accordance with an illustrative embodiment. Method 2100 may be used to create any of the delta sigma modulators described herein, such as that shown in FIG. 1 or that shown in FIG. 19.

Method 2100 includes placing a digital-to-analog converter (DAC) on a chip (operation 2102). Method 2100 also includes placing, on the chip, an asynchronous successive-approximation register (ASAR) quantizer (QTZ) and connected to the DAC (operation 2014). Method 2100 also includes placing, on the chip, a second order noise coupling circuit (NC) connected to the ASAR and to the DAC (operation 2106).

Still other variations are possible. Thus, the illustrative embodiments are not necessarily limited to the examples provided in FIG. 21.

The description of the different illustrative embodiments has been presented for purposes of illustration and description, and is not intended to be exhaustive or limited to the embodiments in the form disclosed. Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. A delta-sigma modulator comprising:
a loop filter (LF);
a digital-to-analog converter (DAC) connected to an input of the loop filter;
an asynchronous successive-approximation register (ASAR) quantizer (QTZ) connected to the DAC; and
a second order noise coupling circuit (NC) connected to the ASAR and the DAC.

2. The delta-sigma modulator of claim 1, wherein the ASAR further comprises:
an excess loop delay (ELD) compensator built within the ASAR QTZ connected to the NC.

3. The delta-sigma modulator of claim 2, wherein the ELD comprises a second loop filter at an end of the ASAR, the second loop filter configured to buffer and inject a quantization error from the NC back into the second loop filter.

4. The delta-sigma modulator of claim 3, wherein the NC comprises a mixed mode discrete time-continuous time second order noise coupler (DT-CT) connected to the ASAR.

5. The delta-sigma modulator of claim 4, wherein the DT-CT implements a noise transfer function of (1−Z⁻¹)²NTF_{LF}, wherein NTF_{LF} is a fourth order noise transfer function of the loop filter.

6. The delta-sigma modulator of claim 5, wherein the noise coupling structure is realized by a cascade of a discrete time (DT) part and a continuous time (CT) part.

7. The delta-sigma modulator of claim 6, wherein the DT part is implemented by switching two pairs of reference-attenuation capacitors of the DAC.

8. The delta-sigma modulator of claim 7, wherein the CT part is implemented by routing a residue voltage of the two pairs of the reference attenuation capacitors to a summing node of a last integrator of the loop filter via an RC network having a time constant sent to a sample period of the delta-sigma modulator.

9. The delta-sigma modulator of claim 8, wherein all capacitors in the delta-sigma modulator are sized relative to an integration capacitor of the last integrator.

10. The delta-sigma modulator of claim 9 further comprising:
a unity-gain negative feedback path incorporated around the QTZ to stabilize a modulator loop for a predetermined ELD setting.

11. The delta-sigma modulator of claim 10, wherein the DAC is driven directly by an output of the ASAR.

12. The delta-sigma modulator of claim 1, wherein the DAC comprises:
a plurality of complimentary current-steering cells with cascode current sources on both P and N sides; and
a switching quad in a middle of the plurality of complimentary current-steering cells.

13. The delta-sigma modulator of claim 12, wherein the DAC is connected to a power supply.

14. The delta-sigma modulator of claim 1, wherein the delta-sigma modulator comprises a fourth-order feed forward architecture.

15. The delta-sigma modulator of claim 14, wherein the DAC comprises a 4-bit non-return-zero (NRZ) current steering feedback digital-to-analog converter.

16. The delta-sigma modulator of claim 6 further comprising:
a plurality of split-path feed-forward compensated op-amps connected between an output of the DAC and an input of the ASAR.

17. A method of operating a delta-sigma modulator, the delta-sigma modulator comprising a loop filter (LF); a digital-to-analog converter (DAC) connected to an input of the loop filter; an asynchronous successive-approximation register (ASAR) quantizer (QTZ) connected to the DAC; and a second order noise coupling circuit (NC) connected to the ASAR and the DAC; the method comprising:
driving the DAC directly by an output of the ASAR; and
stabilizing a modulator loop by performing a unity-gain negative feedback path around the QTZ.

18. The method of claim 17 further comprising:
calibrating static DAC mismatch errors using a foreground technique.

19. The method of claim 18 further comprising:
quantizing a sine wave by the delta-sigma modulator; and
fitting a curve to extract bit weights of all DAC cells.

20. A method of manufacturing a delta-sigma modulator comprising:
placing a digital-to-analog converter (DAC) on a chip;
placing an asynchronous successive-approximation register (ASAR) quantizer (QTZ) connected to the DAC on a chip; and
placing a second order noise coupling circuit (NC) connected to the ASAR and the DAC on a chip.
